(19) United States
(12) Patent Application Publication
(10) Pub. No.: US 2026/0011608 A1
(43) Pub. Date: Jan. 8, 2026

(54) THREE-DIMENSIONAL CLEAVAGE TECHNIQUES USING STEALTH DICING, AND ASSOCIATED SYSTEMS AND METHODS

(71) Applicant: Micron Technology, Inc., Boise, ID (US)

(72) Inventors: Kyle K. Kirby, Eagle, ID (US); Andrew M. Bayless, Boise, ID (US); Brandon P. Wirz, Boise, ID (US)

(21) Appl. No.: 19/239,705

(22) Filed: Jun. 16, 2025

Related U.S. Application Data
(60) Provisional application No. 63/667,689, filed on Jul. 3, 2024.

(51) Int. Cl. H01L 21/78; H01L 21/268; H01L 21/66

(52) U.S. Cl. CPC H01L 21/78; H01L 21/268; H01L 22/12

(57) ABSTRACT

A stealth dicing process for singulating semiconductor dies from a wafer substrate and associated systems and methods are disclosed herein. In some embodiments, the process includes forming a first cleavage line in a wafer that extends generally in a first direction and defines a first surface corresponding to a sidewall of a semiconductor die. The process can also include forming a second cleavage line in the wafer that extends generally in a second direction perpendicular and defines a second surface oriented generally perpendicular to the first surface. Further, the second surface can correspond to at least a portion of a top surface or at least a portion of a bottom surface of the semiconductor die. In some embodiments, the process forms the second cleavage line for a first semiconductor die at a different depth from the second cleavage line for a second semiconductor die.

### CROSS-REFERENCE TO RELATED APPLICATION(S)

The present application claims priority to U.S. Provisional Patent Application No. 63/667,689, filed Jul. 3, 2024, the disclosure of which is incorporated herein by reference in its entirety.

### TECHNICAL FIELD

The present technology is generally directed to methods for manufacturing semiconductor devices. For example, several embodiments of the present technology are directed to methods for stealth dicing a wafer substrate in three dimensions (e.g., to singulate semiconductor dies with varying thicknesses from a same wafer).

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or failure detectability.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic, cross-sectional side view of a semiconductor device configured in accordance with various embodiments of the present technology.

FIG. 2A is a partially schematic, cross-sectional side view of an environment for stealth dicing a wafer substrate in accordance with various embodiments of the present technology.

FIGS. 2B and 2C are partially schematic top-plan views of the wafer substrate of FIG. 2A during various stages of a stealth dicing process in accordance with various embodiments of the present technology.

FIGS. 3A-3C are partially schematic cross-sectional side views of an environment for removing semiconductor dies from a wafer substrate after stealth dicing in accordance with various embodiments of the present technology.

FIG. 3D is a partially schematic cross-sectional side view of a semiconductor die resulting from the process of FIGS. 3A-3C in accordance with various embodiments of the present technology.

FIG. 4 is a flow diagram illustrating a process for stealth dicing one or more semiconductor dies from a wafer substrate in accordance with various embodiments of the present technology.

FIG. 5 is a partially schematic cross-sectional side view of a wafer substrate illustrating results from various stealth dicing processes in accordance with further embodiments of the present technology.

FIG. 6 is a partially schematic cross-sectional side view of a wafer substrate illustrating results from various stealth dicing processes in accordance with further embodiments of the present technology.

FIGS. 7A and 7B are partially schematic cross-sectional side views of an environment for replacing semiconductor dies in a wafer substrate in accordance with various embodiments of the present technology.

FIG. 8 is a partially schematic cross-sectional side view of a wafer substrate illustrating results from various stealth dicing processes in accordance with further embodiments of the present technology.

FIG. 9A is a partially schematic cross-sectional side view of a wafer substrate illustrating results from various stealth dicing processes in accordance with further embodiments of the present technology.

FIG. 9B is a partially schematic cross-sectional side view of a stacked semiconductor device configured in accordance with various embodiments of the present technology.

FIG. 9C is a partially schematic cross-sectional side view of a portion of a stacked semiconductor device configured in accordance with various embodiments of the present technology.

FIG. 10 is a partially schematic cross-sectional side view of a wafer substrate illustrating results from various stealth dicing processes in accordance with further embodiments of the present technology.

### DETAILED DESCRIPTION

As discussed in more detail below, the present disclosure is directed to stealth dicing processes for singulating dies from wafers or other substrates. The stealth dicing processes can include forming a plurality of voids at varying depths within a wafer to customize a three-dimensional profile of each of the dies before they are removed from the wafer. For example, a plurality of voids can define cleavage lines along intended bottom surfaces for multiple dies extracted from a same wafer. Because the depth of the voids formed within the wafer is controllable, a bottom surface for a first die can be defined using a first set of voids formed at a first depth within the wafer and a bottom surface for a second die can be defined using a second set of voids formed at a second, different depth within the wafer. Thus, at least when the first and second dies are singulated from the wafer, the first die can have a different thickness from the second die despite being extracted from the same wafer. Additionally, or alternatively, various stealth dicing processes of the present technology can include forming voids within a substrate to define stepped profiles, cavities, channels, angled and/or sloped profiles, curved profiles, and/or other features or characteristics in, for example, the upper surface, sidewalls, and/or bottom surface of semiconductor dies. Therefore, the stealth dicing processes and techniques disclosed herein can be leveraged to expand customizability of three-dimensional profiles of the dies.

Additionally, or alternatively, the stealth dicing processes and techniques disclosed herein can be employed to remove and/or replace individual dies at the wafer level. For example, the stealth dicing processes disclosed herein can be used to form cleavage lines around a die identified to contain manufacturing defects and/or other faults (also referred to herein as a “known bad die”). The identified die can then be removed and/or replaced (e.g., backfilled) with a functional/non-defective die (also referred to herein as a “known good die”), such as without singulating other (e.g., functional or known good) dies from the wafer. As a result, for example, stealth dicing processes disclosed herein can be leveraged to produce an entire wafer of functional dies.

Although the systems and methods discussed herein are discussed primarily with reference to stealth dicing processes that are usable to remove semiconductor dies from a wafer, one of skill in the art will understand that the processes of the present technology discussed herein are not so limited. Purely by way of example, various stealth dicing processes of the present technology can be utilized to isolate any suitable structure after wafer-level processing. Additionally, although the stealth dicing processes of the present technology are discussed primarily herein for customizing semiconductor dies for a stacked semiconductor device, one of skill in the art will understand that the stealth dicing process can be used to form semiconductor dies for any other suitable use (e.g., for a high-bandwidth memory devices, other packages, and/or the like).

As used herein, the terms “vertical,” “lateral,” “upper,” “lower,” “top,” and “bottom” can refer to relative directions or positions of features in the SiP devices in view of the orientation shown in the drawings. For example, “bottom” can refer to a feature positioned closer to the bottom of a page than another feature. These terms, however, should be construed broadly to include SiP devices having other orientations, such as inverted or inclined orientations where top/bottom, over/under, above/below, up/down, and left/right can be interchanged depending on the orientation.

The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

Further, unless the context indicates otherwise, structures disclosed herein can be formed using one or more semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques.

Current dicing techniques involve dicing partway through a thickness of a wafer (in the z direction) with a mechanical blade (e.g., to form a grid of trenches), and then grinding away the back of the wafer until the trenches are exposed and the wafer is diced into separate devices. Use of a mechanical blade, however, involves a kerf line corresponding to wasted material due to the width of the blade.

Current stealth dicing techniques, by contrast, employ lasers to irradiate silicon wafers in the z-direction (through a thickness of the wafer) and along trenches/die streets (in the x and/or y directions) to, for example, form grids of perforations in the wafers. As parts of a silicon wafer are irradiated by a laser, those parts heat up and swell, and then subsequently shrink as they cool, resulting in mechanical damage to (e.g., weaking of) those parts to form the perforations. After being irradiated, excess silicon of the wafer can be removed via back grinding, and the perforated silicon portion of the wafer that remains can be placed on tape. Thereafter, the tape can be expanded radially such that the wafer breaks/cracks along the mechanically weakened trench/cleavage lines. There is no kerf line when using a laser, so stealth dicing avoids the wasted material inherent in using a mechanical blade.

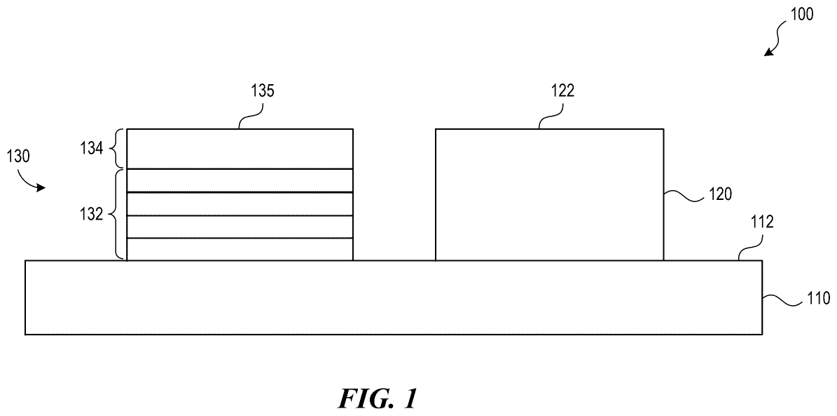

For the sake of clarity and understanding of the description of the present technology provided below with reference to FIGS. 1-10, a detailed discussion of current stealth dicing techniques is provided here. In many stealth dicing processes, a stealth dicing system uses a laser to trace an outline of a plurality of semiconductor dies formed in a wafer. The outline corresponds to sidewalls of the semiconductor dies. More specifically, the laser concentrates energy at a depth into the wafer to create voids (e.g., microbubbles caused by swelling and/or contraction) along shared sidewalls between the dies as the stealth dicing system scans, thereby forming a grid of perforations within the wafer. The depth is typically constant and corresponds to a midpoint along the shared sidewalls such that the voids created in the wafer track the sidewalls along a midpoint line of the sidewalls. As discussed above, the voids (sometimes referred to herein as “microbubbles,” “wafer perforations,” and/or the like) are structural weak points. Once the stealth dicing system has traced the outline (corresponding to sidewalls) of each of the dies, excess material can be removed from the wafer via a backgrinding process until the wafer is at a final thickness for the dies formed therein. After backgrinding, the wafer can be attached to a tape that is expanded to apply tensile stress to the wafer. The tensile stress, in turn, causes cracks to form and propagate vertically (a) from the tape, (b) to and through the voids (e.g., the weak points), and (c) to the opposite side of the dies. Because the voids are formed along the sidewalls of the dies, the cracks singulate the dies in the wafer.

The cracks formed by a stealth dicing process travel in a generally straight, vertical direction and singulate the dies without requiring material to be removed between them. As a result, stealth dicing can require significantly less space between dies for dicing streets than other methods of singulation (e.g., blade dicing, laser ablation, and/or the like). In turn, the narrower dicing streets of the stealth dicing process can allow additional dies to be packed onto the wafer, thereby reducing manufacturing costs. Additionally, in comparison to other singulation technology (e.g., blade dicing), the cracks that result from stealth dicing result in fewer impurities (e.g., chipping, scattered material, and/or the like) that, if present, can undermine the quality and/or lifespan of the resulting dies.

Current stealth dicing techniques, however, are merely used to form planar cleavage interfaces along die streets as part of dicing a wafer. Stated another way, current stealth dicing techniques involve using lasers merely to form flat/planar cleavage interfaces that correspond to flat/planar sidewalls of singulated dies. In addition, the depth of voids formed in wafer using current stealth dicing techniques is typically uniform across the wafer, leading to relatively uniform heights of dies singulated from the wafer after backgrinding. Thus, current stealth dicing techniques are limited to forming/defining planar cleavage interfaces, do not enable retrieval of dies having different heights from the same wafer, and still involve a backgrinding process (constituting a waste of silicon). Thus, employing current stealth dicing techniques can require post-wafer processing to form dies with different shapes, thicknesses, and/or other attributes.

To address these concerns, the present technology is directed to stealth dicing processes/techniques that are usable to stealth dice a wafer in three dimensions (e.g., as opposed to merely forming trenches along die streets in a wafer). For example, several stealth dicing processes described below include forming bottom cleavage lines for each of a plurality of dies in a wafer substrate. The bottom cleavage lines may be formed at varying depths. For example, various stealth dicing processes described herein can include forming a first bottom cleavage line for a first die at a first depth within the wafer substrate and forming a second bottom cleavage line for a second die at a second depth within the wafer substrate. Each of the bottom cleavage lines can be formed or realized using a plurality of voids at the corresponding depth. To form first voids corresponding to the first bottom cleavage line, the stealth dicing processes can include focusing a laser of a stealth dicing system at the first depth. Material in the wafer substrate can swell around a focus point of the laser, thereby creating a void (or mechanical weak point) in the wafer at the focus point. The stealth dicing processes can also include scanning the laser along one or more first motion paths that include a plurality of (e.g., horizontal) scribe lines through the first die. As the laser moves along the first motion path(s), the laser can create the plurality of first voids for the first bottom cleavage line. Similarly, to form second voids corresponding to the second bottom cleavage line, the stealth dicing processes can include focusing the laser at the second depth and scanning the laser along one or more second motion paths that include a plurality of (e.g., horizontal) scribe lines through the second semiconductor die. As the laser moves along the second motion path(s), the laser can create the plurality of second voids for the second bottom cleavage line. Similar processes can then be repeated for any suitable number of dies in the wafer substrate.

Additionally, continuing with the above example, several stealth dicing processes described herein can include forming a plurality of side cleavage lines around a perimeter of the dies (e.g., generally corresponding to the sidewalls of the dies). Each of the side cleavage lines can include one or more third voids. Similar to the discussion above, to form the third voids, various stealth dicing processes of the present technology can include focusing a laser at a third depth shallower than the first and/or second depths and scanning the laser along a third motion path. The third motion path can trace the sidewalls of dies in the wafer substrate at the third depth. In embodiments where each of the third cleavage lines includes two or more voids, various stealth dicing processes of the present technology can include focusing the laser at a fourth (and fifth, and so on) depth shallower than the third depth and scanning the laser along a fourth motion path. The fourth motion path can trace the sidewalls of dies in the wafer substrate at the fourth depth.

As discussed in more detail below, stealth dicing processes described herein can additionally, or alternatively, be used to customize a shape (e.g., a three-dimensional outline) of dies. For example, various stealth dicing processes of the present technology can be used to form channels in a top or bottom surface of one or more of the dies that can, for example, help dissipate heat away from the die(s) when included in a stacked semiconductor device. As another example, various stealth dicing processes of the present technology can be used to form one or more steps (e.g., slots, cutouts, recesses) to lower a height of one or more bond pads on the dies (e.g., to make an intermediate die in a die stack directly accessible to a wirebond), form a beveled and/or tapered outline for one or more of the dies, form a curved profile for one or more of the dies, and/or the like. Additional details on stealth dicing processes of the present technology are described in more detail below with reference to FIGS. 1-10.

FIG. 1 is a partially schematic cross-sectional side view of a semiconductor device 100 configured in accordance with various embodiments of the present technology. In the illustrated embodiment, the semiconductor device 100 includes a base substrate 110, as well as a processing unit 120 and a stack 130 of semiconductor dies carried by an upper surface 112 of the base substrate 110. The base substrate 110 can be a printed circuit board (PCB), an interposer, and/or any other suitable substrate. Further, the base substrate 110 can support and/or interconnect the processing unit 120 and the stack 130 of semiconductor dies 130 (the “die stack 130”). Purely by way of example, the base substrate 110 can include a plurality of route lines and/or a redistribution layer (not shown) formed in the upper surface 112 to couple the processing unit 120 to the die stack 130. Additionally, or alternatively, the base substrate can include various metallization layers and/or interconnects that allow the processing unit 120 and/or the die stack 130 to be coupled to various other components of a semiconductor system (e.g., another controller, a package substrate, one or more storage devices, and/or the like).

The processing unit 120 can be a host device for a system-in-package (SiP) device (e.g., when the base substrate is a silicon interposer), a graphics processing unit (GPU), computer processing unit (CPU), and/or a package controller, and/or any other suitable device. Similarly, the die stack 130 can include any suitable combination of semiconductor dies. For example, the die stack 130 can include one or more DRAM dies (e.g., when the semiconductor device 100 is a SiP device), other memory dies (e.g., NAND dies), logic dies, controller dies, and/or any other suitable semiconductor dies.

As further illustrated in FIG. 1, the die stack 130 can include one or more first dies 132 (four illustrated in FIG. 1) that have a first height as well as a second die 134 (e.g., an uppermost die in the die stack 130) that has a second height. The first height can correspond to a standard height for the dies in the die stack following wafer-level manufacturing. The second die 134, in contrast, can be formed with the second height to, for example, specifically place an uppermost surface 135 of the die stack 130 at generally the same height as a top surface 122 of the processing unit 120. Said another way, the second die 134 can be formed with a custom thickness (e.g., such that the uppermost surface 135 of the die stack 130 is coplanar (or generally coplanar) with the top surface 122 of the processing unit 120). General alignment in the height of the uppermost surface 135 and the top surface 122 can allow, for example, a heat sink (not shown) and/or any other suitable additional component to be stacked over the processing unit 120 and the die stack 130. Additionally, or alternatively, general alignment in the height of the uppermost surface 135 and the top surface 122 can allow the semiconductor device to be integrated into a larger stack of semiconductor devices.

Although shown as the uppermost die in the die stack 130, the second die 134 can be positioned elsewhere in the stack 130 in other embodiments of the present technology. For example, the second die 134 can be a bottommost die of the die stack 130 or a die positioned in the middle of the die stack 130 in other embodiments of the present technology. Additionally, or alternatively, although shown with a single second die 134 in the illustrated embodiment, the die stack 130 can include multiple second dies 134 in other embodiments of the present technology. In these and other embodiment, the die stack 130 can include a third die having a third height or thickness that is different (e.g., is larger and/or smaller) than the first and/or second heights. In these and still other embodiments, the semiconductor device 100 can include multiple die stacks. For example, the semiconductor device 100 can include a second die stack (e.g., in lieu of the processing unit 120), and the differing thickness/height of the second die 134 can be used to achieve general alignment between the die stack 130 and the second die stack.

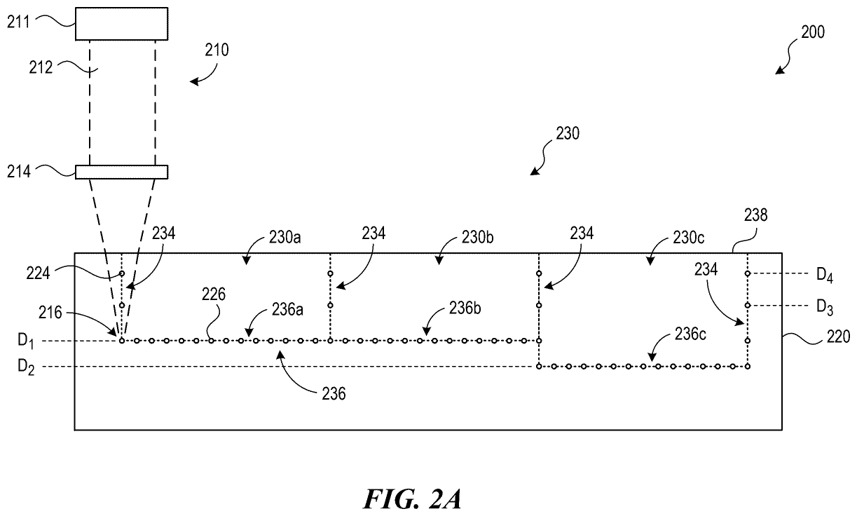

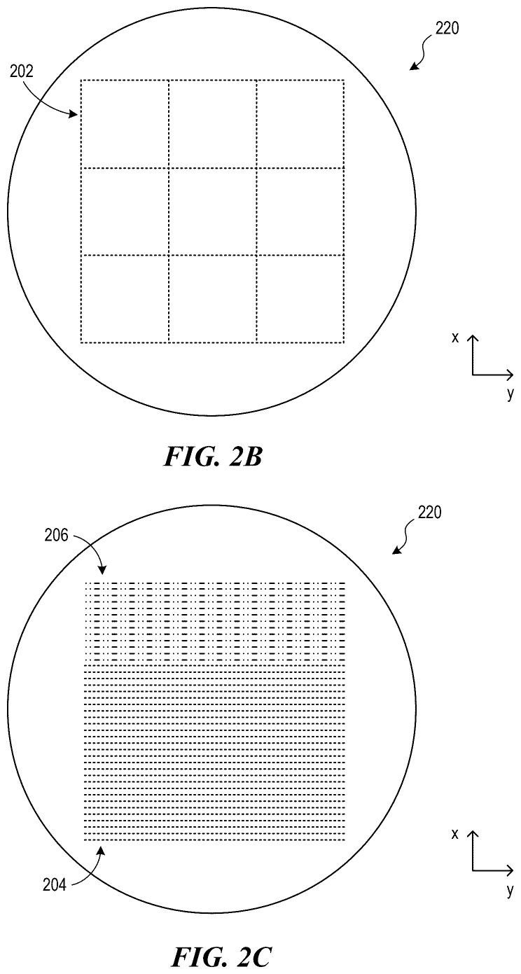

FIG. 2A is a partially schematic cross-sectional side view of an environment 200 for stealth dicing a wafer substrate 220 in accordance with various embodiments of the present technology. In the illustrated embodiment, the environment 200 includes the wafer substrate 220 and a stealth dicing system 210. The stealth dicing system 210 includes a laser generation component 211 configured to generate a laser 212 (e.g., an infrared laser), as well as a focusing component 214 (e.g., optical components such as one or more lens, mirrors, and/or the like) positioned to help direct and focus the laser 212.

During various stealth dicing processes of the present technology, the focusing component 214, can create a focus point 216 for the laser 212 at a predetermined depth within the wafer substrate 220. The stealth dicing system 210 can then trace an outline (e.g., a perimeter) of each of a plurality of semiconductor dies 230 (three illustrated in FIG. 2A, identified to individually as first through third semiconductor dies 230a-230c) formed in the wafer substrate 220 to create a plurality of first voids 224 around the perimeter of each of the semiconductor dies 230. As discussed above, the first voids 224 (sometimes referred to herein as “perimeter voids,” “peripheral perforations,” and/or the like) help originate and direct cracks vertically through the wafer substrate 220 in response to tensile stress thereon, allowing the semiconductor dies to be singulated. Accordingly, the first voids 224 define side cleavage lines 234 for the semiconductor dies 230 (e.g., corresponding to what will become sidewalls for the semiconductor dies 230 when they are removed from the wafer substrate 220) that extend in a generally vertical direction (e.g., a first direction). Said another way, the first voids 224 define the side cleavage lines 234 in various two-dimensional planes around the perimeter of each of the semiconductor dies 230. In the illustrated embodiment, each of the semiconductor dies 230 is formed adjacent to each other so that the side cleavage lines 234 are positioned along corresponding sidewalls of the semiconductor dies 230 (e.g., one of the cleavage lines 234 separates (or demarcates) a right sidewall of the first semiconductor die 230a from a left sidewall of the second semiconductor die 230b).

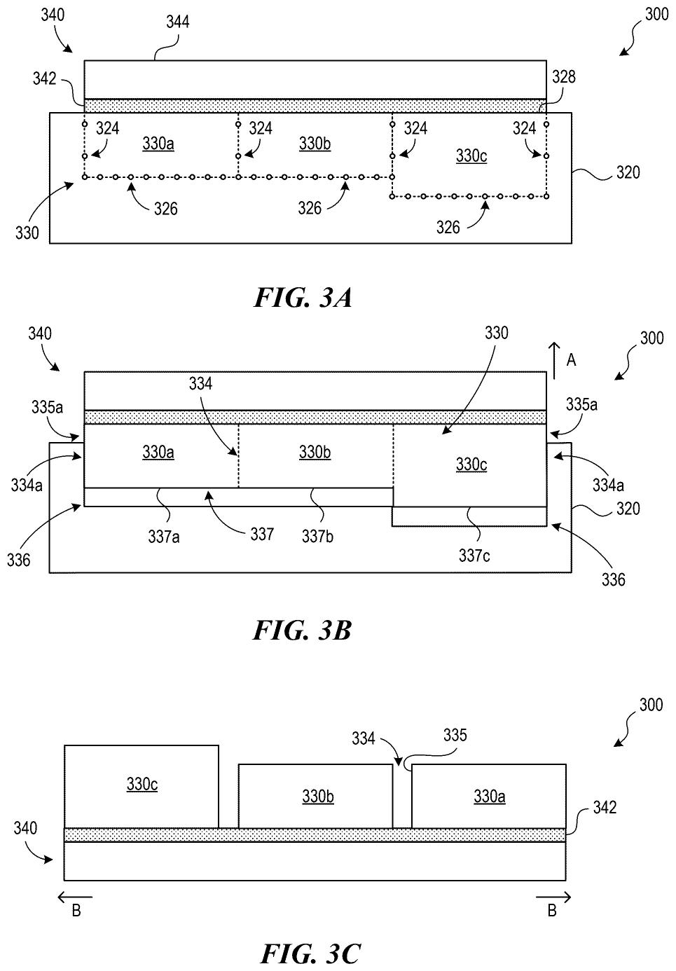

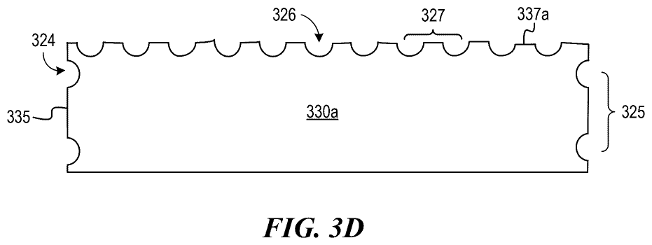

Additionally, or alternatively, the stealth dicing system 210 can pass back and forth in the horizontal direction to form a plurality of second voids 226 along a bottom cleavage line 236 of the semiconductor dies 230 (e.g., corresponding to a bottom or top surface of the semiconductor dies 230 once they are separated from the wafer substrate 220). Similar to the first voids 224, the second voids 226 (sometimes referred to herein as “depth voids,” bottom perforations,” and/or the like) can help initiate and guide cracks or breaks through the wafer substrate 220. In contrast to the side cleavage lines 234, the bottom cleavage line 236 (sometimes also referred to herein as a “horizontal cleavage line,” a “depth cleavage line,” and/or the like) can extend in a generally horizontal direction (e.g., a second direction) within the wafer substrate 220. Said another way, the bottom cleavage line 236 can be generally (or exactly) perpendicular to the side cleavage lines 234. Said yet another way, the second voids 226 define the bottom cleavage line 236 in various two-dimensional planes at the bottom (or top) surface of each of the semiconductor dies 230 within the wafer substrate 220. Further, in contrast to the first voids 224, the second voids 226 can help propagate cracks in a horizontal direction along the bottom cleavage line 236 of the semiconductor dies 230, such as in response to a pulling force on the semiconductor dies (discussed in more detail below with reference to FIGS. 3A and 3B). As further illustrated in FIG. 2A, the side cleavage lines 234 intersect with the bottom cleavage line 236 for each of the semiconductor dies 230, thereby completely framing each of the semiconductor dies 230. As a result, the second voids 226 can allow the semiconductor dies 230 to be removed from the wafer substrate 220 at a predetermined depth. In some embodiments, the predetermined depth corresponds to a final thickness for the semiconductor dies 230, which can obviate the practice of backgrinding the dies to a desired thickness. Further, as illustrated in FIG. 2A, the side cleavage lines 234 can intersect with the bottom cleavage line 236 for each of the semiconductor dies 230. Said another way, the side and bottom cleavage lines 234, 236 can completely frame each of the semiconductor dies 230 in the wafer substrate 220. As a result, for example, the side and bottom cleavage lines 234, 236 can allow the semiconductor dies 230 to be individually removed from the wafer substrate 220.

As further illustrated in FIG. 2A, the bottom cleavage line 236 of the semiconductor dies 230 can vary throughout the wafer substrate 220. For example, the focusing component 214 can be moved to shift the focus point 216 of the laser 212 in a vertical direction between scans along the bottom cleavage line 236 of one of the semiconductor dies 230. In the illustrated embodiment, for example, the second voids 226 are at a first depth D₁ for the first and second semiconductor dies 230a, 230b and are at a second depth D₂ for the third semiconductor die 230c. As a result, the first and second semiconductor dies 230a, 230b have first and second bottom cleavage lines 236a, 236b, respectively, at the first depth D₁ while the third semiconductor die 230c has a third bottom cleavage line 236c at the second depth D₂. In turn, when the semiconductor dies 230 are removed from the wafer substrate 220, the first and second semiconductor dies 230a, 230b can crack or break along the first and second bottom cleavage lines 236a, 236b at the first depth D₁ while the third semiconductor die 230c can crack or break along the third bottom cleavage line 236c at the second depth D₂. As a result, stealth dicing processes of the present technology can be leveraged to form the semiconductor dies 230 with varying thicknesses.

Said another way for the sake of clarity, when the semiconductor dies 230 are pulled upwards, the first and second semiconductor dies 230a, 230b will break from the wafer substrate 220 along the first and second bottom cleavage lines 236a, 236b at the first depth D₁. As a result, the first and second semiconductor dies 230a, 230b will have a first height corresponding to a distance between the first and second bottom cleavage lines 236a, 236b and an upper surface 238 of the semiconductor dies 230. In contrast, the third semiconductor die 230c will break from the wafer substrate 220 along the third bottom cleavage line 236c at the second depth D₂ and therefore have a second height corresponding to a distance between the third bottom cleavage line 236c and the upper surface 238. Because the second depth D₂ is greater than the first depth D₁, the second height will be greater than the first height (e.g., such that the third semiconductor die 230c will be thicker than the first and second semiconductor dies 230a, 230b). The varying heights (and varying thicknesses) can be useful, for example, to form the first and second dies 132, 134 discussed above with reference to FIG. 1 within the same wafer and/or without requiring additional backgrinding processes to form such dies.

As further illustrated in FIG. 2A, various stealth dicing processes of the present technology can include forming the first voids 224 at multiple depths within the wafer substrate 220 (e.g., at multiple points along each of the side cleavage lines 234). For example, the stealth dicing system can trace a perimeter of each of the semiconductor dies 230 at a third depth D₃, adjust the focusing component 214 to concentrate the laser 212 at a fourth depth D₄, and then trace the perimeter of each of the semiconductor dies 230 again. When tensile force is applied to the wafer substrate 220, cracks can propagate vertically between each of the first voids 224. As a result, it is expected that cracks will be less likely to drift in a horizontal direction as they propagate vertically, thereby reducing the chance that the singulation process accidentally destroys circuits adjacent to the perimeter of the semiconductor dies. Said another way, forming the first voids 224 at multiple depths along the side cleavage lines 234 of the semiconductor dies 230 is expected to reduce the chance that cracks drift outside of the intended singulation lanes.

FIGS. 2B and 2C are partially schematic top-plan views of the wafer substrate 220 of FIG. 2A during various stages of stealth dicing processes in accordance with various embodiments of the present technology. More specifically, FIG. 2B schematically illustrates first motion paths 202 for the focus point of a stealth dicing system (e.g., the focus point 216 of FIG. 2A) while forming the first voids 224 (FIG. 2A) in the wafer substrate 220. As illustrated, the first motion paths 202 scan the stealth dicing system 210 in the x-y direction to trace a perimeter of the semiconductor dies 230 (FIG. 2A). The first motion paths 202 do not, however, move the focus point stealth dicing system through a center of any of the semiconductor dies 230.

FIG. 2C, in contrast, schematically illustrates second and third motion paths 204, 206 for the focus point of the stealth dicing system (e.g., the focus point 216 of FIG. 2A) while forming the second voids 226 (FIG. 2A) in the wafer substrate 220. As illustrated, each of the second and third motion paths 204, 206 includes scribe lines that pass through a central portion of the semiconductor dies 230 (FIG. 2A) to allow the stealth dicing system to form the second voids 226 (FIG. 2A) along the bottom cleavage lines 236 of the semiconductor dies. Further, each of the second and third motion paths 204, 206 can be generally similar to each other (e.g., scanning across the wafer in the y-direction, scanning across the wafer in the x-direction, and/or scanning across the wafer in any other suitable direction in the x-y plane). A depth of the focus point of the stealth dicing system can be adjusted between the second and third motion paths 204, 206. For example, the stealth dicing system can focus the laser 212 (FIG. 2A) at the first depth D₁ for each of the second motion paths 204 then focus the laser 212 at the second depth D₂ for each of the third motion paths 206. As a result, the scribe lines of the second motion paths 204 can form the first and second bottom cleavage lines 236a, 236b (FIG. 2A) while the scribe lines of the third motion paths 206 can form the third bottom cleavage line 236b.

It will be understood that although two motion paths with varying depths are illustrated in FIG. 2C, the stealth dicing system 210 can have any other suitable number of motion paths at varying depths. In some embodiments, for example, the stealth dicing system 210 is reconfigured to adjust the depth for each individual semiconductor die on the wafer substrate 220 and has a corresponding motion path for each of the individual semiconductor dies. Further, in some embodiments, as discussed in more detail below, the stealth dicing system 210 adjusts the depth of the focus point while moving along a motion path. In such embodiments, the stealth dicing system 210 can help form semiconductor dies with non-square edges (e.g., with a sloped surface, a stepped surface, and/or the like).

FIGS. 3A-3C are partially schematic cross-sectional side views of an environment 300 for singulating semiconductor dies 330 from a wafer substrate 320 using various stealth dicing processes in accordance with various embodiments of the present technology. In the illustrated embodiment, the wafer substrate 320 is generally similar to the wafer substrate 220 resulting from the laser scanning processes discussed above with reference to FIGS. 2A-2C. For example, as illustrated in FIG. 3A, the wafer substrate 320 includes first and second semiconductor dies 330a, 330b that are outlined by first and second voids 324, 326 to a first depth within the wafer substrate 320. The wafer substrate 320 also includes a third semiconductor die 330c that is outlined by the first and second voids 324, 326 to a second depth within the wafer substrate 320 deeper than the first depth. Accordingly, forces applied to the wafer substrate 320 can propagate cracks through the wafer substrate 320 to remove and/or singulate the semiconductor dies 330.

For example, as illustrated in FIG. 3A, the stealth dicing process can include engaging the upper surface 328 of one or more of the semiconductor dies 330 with a die-removal component 340. In the illustrated embodiment, the die-removal component 340 includes a die-attach film 342 and a carrying substrate 344 (e.g., a carrier wafer, a carrying film, and/or the like). Further, the die-attach film 342 can be bonded to the upper surface 328 of each of the semiconductor dies 330 to remove each of the semiconductor dies 330 from unused portions of the wafer substrate 320 (e.g., at once).

As illustrated in FIG. 3B, after the die-removal component 340 engages the one or more semiconductor dies 330, the die-removal component 340 can apply an upward force (e.g., generally along or parallel to arrow A) to the semiconductor dies 330. The upward force (sometimes also referred to herein as an “outward force,” a “die-separation force,” and/or the like) causes cracks to form and propagate horizontally through the wafer substrate 320 along bottom cleavage lines 336 defined by voids 326 (FIG. 3A) in the wafer substrate 320, as well as vertically along the peripheral-most side cleavage lines 334a, 334b of the semiconductor dies 330 engaged by the die-removal component 340. Once the cracks are formed, the die-removal component 340 can lift the semiconductor dies 330 out of and away from the wafer substrate 320 (e.g., in a direction generally along or parallel to the arrow A), thereby exposing bottom surfaces 337 and peripheral-most sidewalls 335a of the semiconductor dies 330. As further illustrated in FIG. 3B, the bottom surfaces 337 are not at the same depth within the wafer substrate 320. For example, similar to the discussion above with reference to FIG. 2A, the third semiconductor die 330c can have a third bottom surface 337c that is at a deeper depth than a first bottom surface 337a of the first semiconductor die 330a and/or a second bottom surface 337b of a second semiconductor die 330b. Said another way, the third semiconductor die 330c can break from the wafer with a larger thickness than either of the first and second semiconductor dies 330a, 330b.

As illustrated in FIG. 3C, the die-removal component 340 can then apply a tensile force (e.g., generally along or parallel to arrows B) to the semiconductor dies 330 (e.g., by spreading the die-attach film 342 in a peripheral direction, sometimes referred to herein as applying a “singulation force”). The tensile force, in turn, causes cracks to form and propagate vertically along the first cleavage lines 334 remaining between the semiconductor dies 330, thereby exposing sidewalls 335 between the semiconductor dies 330. As a result, the tensile force singulates the semiconductor dies 330. Once singulated, the semiconductor dies 330 can be removed from the die-removal component 340 and/or added to a stacked semiconductor device. Purely by way of example, the first and second semiconductor dies 330a, 330b (e.g., the dies with a shorter overall height) can be stacked as the first dies 132 of the die stack 130 of FIG. 1 while the third semiconductor die 330c (e.g., the die with a taller overall height) can be stacked as the second die 134 of FIG. 1.

FIG. 3D is a partially schematic cross-sectional side view of the first semiconductor die 330a after the singulation process described above with reference to FIGS. 3A-3C illustrating additional details on a result of the stealth dicing process. More specifically, FIG. 3D illustrates that a portion of each of the first voids 324 remains in the sidewalls 335 after the stealth dicing process. The remaining portion of the first voids 324 is a result of a crack propagating through a central portion of the first voids 324, thereby leaving the remainder as a minor defect in the sidewalls 335 of the first semiconductor die 330a. Similarly, a portion of each of the second voids 326 remains in the bottom surface 337a of the stealth dicing process, resulting in minor defects in the bottom surface 337a. In some embodiments, the sidewalls 335 and/or the bottom surface 337a are then subjected to a grinding process (e.g., a backgrinding process) to remove a portion of the first semiconductor die 330a to clear the defects. In some embodiments, the defects are left in the sidewalls 335 and/or the bottom surface 337a. The portions of the first and second voids 324 and 326 shown in FIG. 3D are overly accentuated for the sake of clarity and understanding and are not shown to scale.

As further illustrated in FIG. 3D, the first voids 324 can be spaced apart by a first distance 325 while the second voids are spaced apart by a second distance 327. In the illustrated embodiment, the first and second distances 325, 327 can be different from each other. For example, the second voids 326 are packed close together to allow the first semiconductor die 330a to be pulled away from the wafer substrate 320 by the die-removal component 340 (FIG. 3B) without requiring a significant force (e.g., because the crack must propagate across the entire bottom surface 337a at once). In contrast, the first voids 324 can be relatively far apart because the cracks can propagate gradually along the sidewalls 335 in response to the tensile stress discussed above with reference to FIG. 3C. As a result, the first distance 325 is greater than the second distance 327. In other embodiments, the first distance 325 can be less than the second distance 327 (e.g., when the first voids 324 are relatively close together to help mitigate crack meandering in the first semiconductor die 330a). In still other embodiments, the first distance 325 can be generally equal to the second distance.

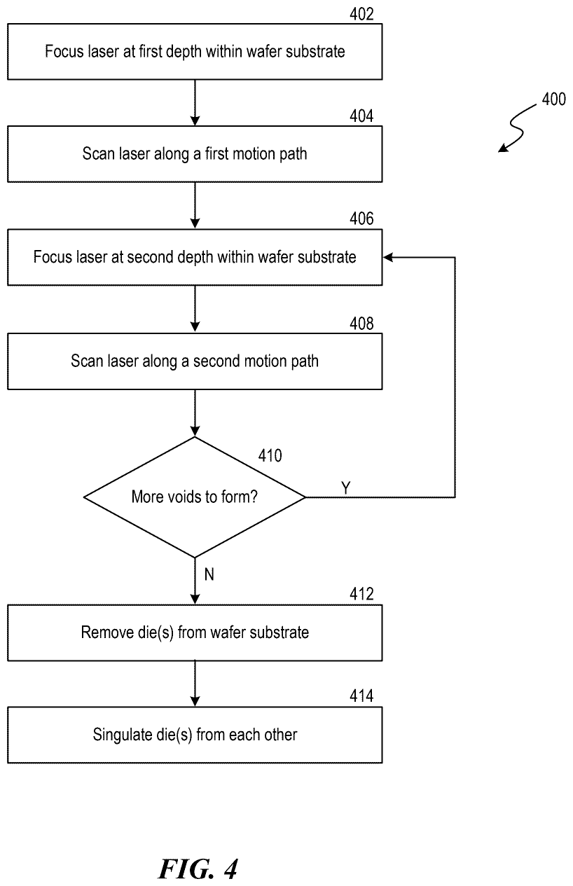

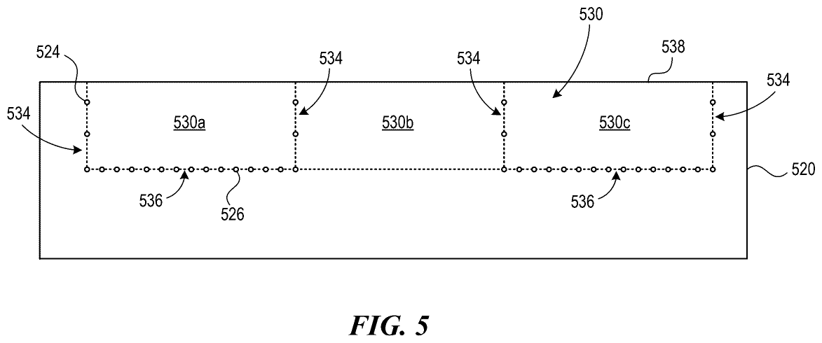

FIG. 4 is a flow diagram illustrating a process 400 for stealth dicing one or more semiconductor dies from a wafer substrate in accordance with various embodiments of the present technology. More specifically, the process 400 illustrated in FIG. 4 generally follows various stealth dicing processes discussed above with reference to FIGS. 2A-3D. The process 400 can be generally executed by, for example, the stealth dicing system 210 of FIG. 2A, one or more controllers coupled thereto, and/or other suitable stealth dicing systems. The process 400 is illustrated as a set of steps or blocks 402, 404, 406, 408, 410, 412, and 414. All or a subset of one or more of these blocks 402, 404, 406, 408, 410, 412, and 414 can be executed in accordance with the discussion (e.g., of FIGS. 2A-3C) above and/or with the discussion of FIGS. 5-10 below. Indeed, several of the blocks 402, 404, 406, 408, 410, 412, and 414 of the process 400 are described below with reference to the wafer substrates 220, 320 illustrated in FIGS. 2A-3C.

The process 400 begins at block 402 by focusing a laser at a first depth within a wafer substrate. The first depth can correspond to a bottom surface of one or more first semiconductor dies formed in the wafer substrate (e.g., the first depth D₁ illustrated in FIG. 2A) and/or an intermediate depth within the wafer substrate (e.g., a depth of one of the first voids 224 illustrated in FIG. 2A). In some embodiments, focusing the laser at the first depth includes moving an optical element (e.g., the focusing component 214 of FIG. 2A) with respect to a laser source (e.g., the laser generation component 211 of FIG. 2A). In some embodiments, focusing the laser at the first depth includes moving the laser source with respect to the wafer substrate.

At block 404, the process 400 includes scanning the laser along a first motion path. In some embodiments, the first motion path traces a perimeter of the semiconductor die(s) at the first depth (e.g., similar to the first motion paths 202 illustrated in FIG. 2B). In some embodiments, the first motion path includes one or more passes through a footprint of the semiconductor die(s) to form one or more cleavage lines at the first depth (e.g., similar to the second and third motion paths 204, 206 illustrated in FIG. 2C). As the laser moves along the first motion path, the laser can form voids within the wafer substrate at the first depth (e.g., thereby forming the first or second voids 224, 226 of FIG. 2A).

At block 406, the process 400 includes focusing the laser at a second depth within the wafer substrate. The second depth can correspond to a bottom surface of one or more second semiconductor dies formed in the wafer substrate (e.g., the second depth D₂ illustrated in FIG. 2A) and/or an intermediate depth within the wafer substrate (e.g., a depth of one of the first voids 224 illustrated in FIG. 2A). Similar to the discussion above, focusing the laser at the second depth can include moving one or more optical components with respect to the laser source and/or moving the laser source with respect to the wafer substrate.

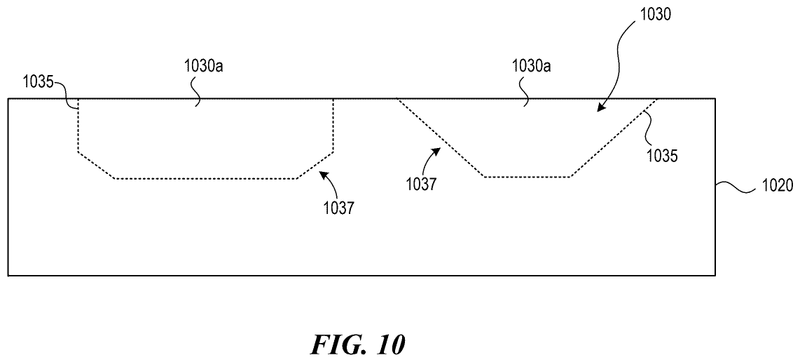

At block 408, the process 400 includes scanning the laser along a second motion path. In some embodiments, the second motion path traces a perimeter of the semiconductor die(s) at the second depth (e.g., similar to the first motion paths 202 illustrated in FIG. 2B). As discussed in more detail below with reference to FIG. 10, the perimeter of the semiconductor die(s) can be different at the second depth than at the first depth, thereby allowing the process to form a sloped cleavage line for the sidewall of one or more of the semiconductor die(s). In some embodiments, the second motion path includes one or more passes through a footprint of the semiconductor die(s) to form one or more cleavage lines at the second depth (e.g., similar to the second and third motion paths 204, 206 illustrated in FIG. 2C). As the laser moves along the second motion path, the laser can form voids within the wafer substrate at the first depth (e.g., thereby forming the first or second voids 224, 226 of FIG. 2A).

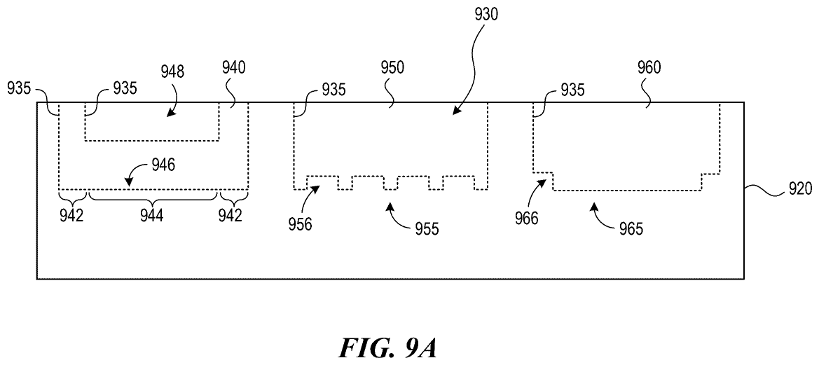

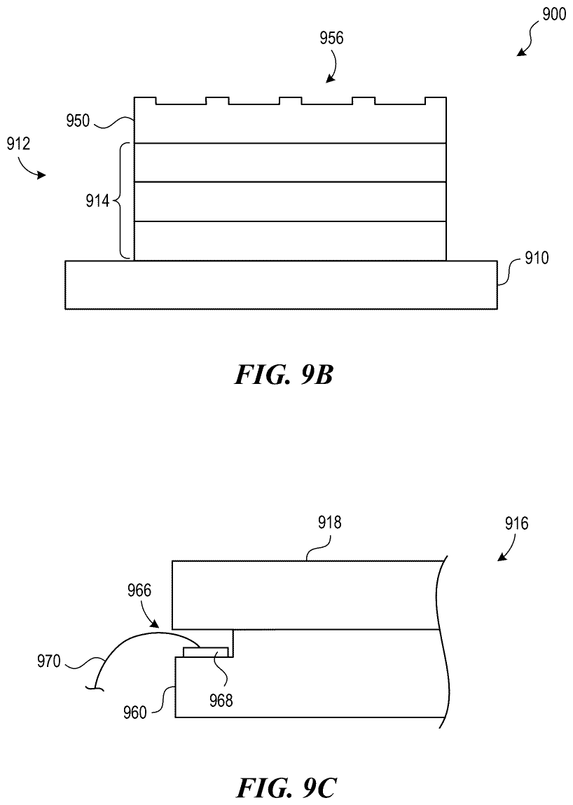

At decision block 410, if there are more voids to be formed, the process 400 returns to block 406 and block 408, else the process 400 moves on to block 412. When returning to block 406, the process 400 can focus the laser at another depth within the wafer substrate, move the laser along another motion path at block 408, then return to decision block 410 to check whether there are more voids to be formed. The return can allow the process 400 to, for example, form the bottom cleavage lines 236 (FIG. 2A) at different depths within the wafer substrate for different semiconductor die(s). Additionally, or alternatively, the return can allow the process 400 to form one or more cavities and/or steps in the semiconductor die(s) (e.g., as discussed below with reference to FIGS. 9A-9C). Additionally, or alternatively, the return can allow the process 400 to form multiple voids along the sidewalls of the semiconductor die(s) (e.g., the first voids 224 of FIG. 2A). The multiple voids can allow, for example, the sidewall to be sloped and/or curved (e.g., as discussed below with reference to FIG. 10) while minimizing the chance a crack meanders outside of the intended sidewall during singulation.

At block 412, the process 400 includes removing the semiconductor die(s) from the wafer substrate (e.g., as illustrated above with reference to FIGS. 3A and 3B). Removing the semiconductor die(s) from the wafer substrate can include engaging an upper surface of the semiconductor die(s) with a die-removal component (e.g., a carrier wafer, a carrying film, and/or the like), then applying an upward and/or outward force to the upper surface of the semiconductor die(s). The upward and/or outward force causes a crack to propagate along one or more cleavage lines within the wafer substrate (e.g., the bottom cleavage lines 336 and/or the peripheral-most side cleavage lines 334a, 334b of FIG. 3B). As a result, the crack propagates between voids along the cleavage lines and releases the semiconductor die(s) from the wafer substrate.

At optional block 414, the process 400 includes singulating the semiconductor dies from each other. The singulation can be achieved by, for example, providing tensile force to the semiconductor dies removed from the wafer substrate (e.g., by the spreading a carrier film attached to the semiconductor dies as illustrated in FIG. 3C) and/or otherwise pulling the semiconductor dies away from each other. The separation force, in turn, causes crack(s) to propagate along cleavage lines between the semiconductor dies (e.g., along the side cleavage lines 334 of FIG. 3C), thereby singulating the semiconductor dies. In embodiments where the semiconductor die(s) are engaged individually by the die-removal component, the process 400 can skip block 414.

Although the blocks 402, 404, 406, 408, 410, 412, and 414 of the process 400 are discussed and illustrated in a particular order, the process 400 illustrated in FIG. 4 is not so limited. In other embodiments, the process 400 can be performed in a different order. In these and other embodiments, any of the blocks 402, 404, 406, 408, 410, 412, and 414 of the process 400 can be performed before, during, and/or after any of the other blocks 402, 404, 406, 408, 410, 412, and 414 of the process 400. For example, all or a subset of blocks 412 and 414 can be executed before decision block 410 to remove and singulate a first set of semiconductor dies before forming cleavage lines around a second set of semiconductor dies. Moreover, a person of ordinary skill in the relevant art will recognize that the illustrated process 400 can be altered and still remain within these and other embodiments of the present technology. For example, one or more blocks 402, 404, 406, 408, 410, 412, and 414 of the process 400 illustrated in FIG. 4 can be omitted and/or repeated in various suitable processes. As a specific example, all or a subset of block 414 can be omitted in some embodiments such that the process 400 completes after block 410. In some such embodiments, the process 400 includes individually engaging and removing the semiconductor dies at block 412 (e.g., via a dir picking mechanism). Additionally, or alternatively, as discussed in more detail below, the process 400 can include replacing one or more of the semiconductor dies before removing a set of the semiconductor dies from the wafer substrate.

FIG. 5 is a partially schematic cross-sectional side view of a wafer substrate 520 illustrating results from various stealth dicing processes in accordance with further embodiments of the present technology. As illustrated in FIG. 5, the results of the stealth dicing processes can be generally similar to those discussed above with reference to FIGS. 2A-2C. For example, the wafer substrate 520 can have a plurality of semiconductor dies 530 formed thereon. Further, as a result of exposure to a laser from the stealth dicing system, the wafer includes first voids 524 defining side cleavage lines 534 and second voids 526 along bottom cleavage lines 536.

As further illustrated in FIG. 5, the stealth dicing processes can form the first and second voids 524, 526 around only a subset of the semiconductor dies 530 (sometimes also referred to herein as “framing the semiconductor dies,” “outline the dies,” and/or the like). In the illustrated embodiment, for example, the wafer substrate 520 includes first, second, and third semiconductor dies 530a, 530b, 530c, but only the first and third semiconductor dies 530a, 530c are surrounded by the first and second voids 524, 526. As a result, only the first and third semiconductor dies 530a, 530c will break from the wafer substrate 520 in response to an upward force on an upper surface 538 of the semiconductor dies 530.

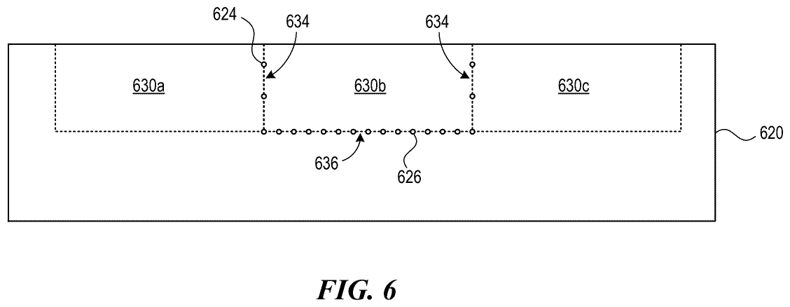

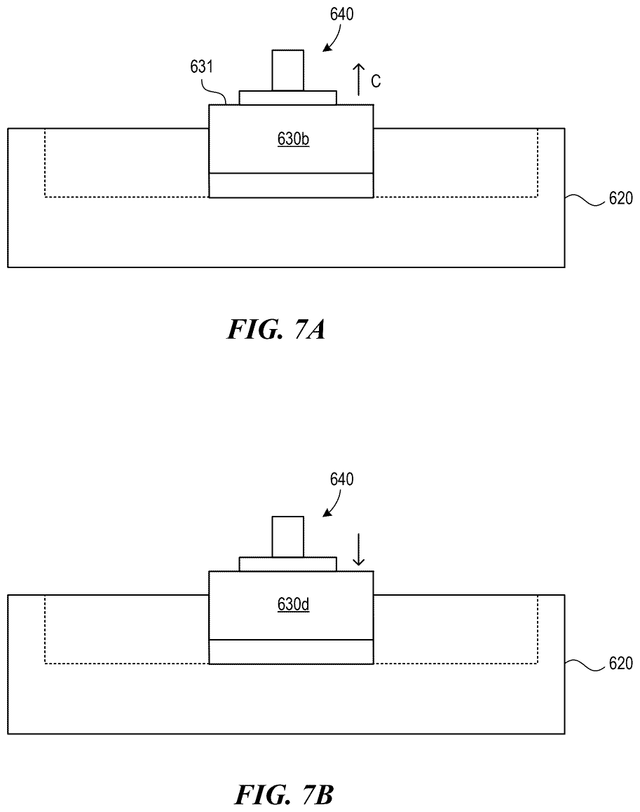

The selective aspect of the stealth dicing process can be utilized in a variety of processes. For example, the stealth dicing process can form first and second voids 524, 526 only around the semiconductor dies 530 that are known good dies (e.g., dies that pass a quality check, such as a functionality test, a visual inspection, and/or any other suitable testing process). In such embodiments, the stealth dicing process does not form the second voids 526 beneath non-functional and/or known bad dies (e.g., the second semiconductor die 530b), thereby helping prevent the known bad dies from being removed from the wafer substrate 520. As a result, the stealth dicing process can save resources associated with forming the second voids, accelerate the formation process, and/or save resources associated with tracking the known bad dies to separate them from the known good semiconductor dies downstream. Additionally, or alternatively, the stealth dicing process can allow known bad dies to be recycled (e.g., scrubbed from the wafer substrate 520 to reuse underlying silicon, used in daisy chain test vehicles, used in test vehicles, and/or the like). Additionally, or alternatively, as discussed in more detail below with reference to FIGS. 6-7B, the stealth dicing process can replace known bad dies on a second wafer substrate with the known good dies from the wafer substrate 520 of FIG. 5.

In another example, the stealth dicing processes can be used to form the first and second voids 524, 526 around only a subset of the semiconductor dies 530 (e.g., dies of a specific type, dies designated for a specific end location, and/or the like), allowing specific subsets of the semiconductor dies 530 to be selectively removed. The selective removal can allow the semiconductor dies 530 to be easily sorted and/or tracked as they are removed from the wafer substrate 520. In a specific, non-limiting example, logic dies can be removed using a first iteration of the stealth dicing processes and stored in a reserve of logic dies. Memory dies (e.g., DRAM dies) can then be removed in a second iteration of the processes. In another specific, non-limiting example, only the dies intended for a first stacked semiconductor device are removed in a first iteration of the stealth dicing processes, and only the dies intended for a second stacked semiconductor device are removed in a second iteration of the stealth dicing process. As a result, the specific dies for the first and second stacked semiconductor devices can be easily tracked and/or managed as they are removed from the wafer substrate 520. As still another specific, non-limiting example, dies of a first height or thickness can be removed using a first iteration of the stealth dicing processes, and dies of a second height or thickness different from the first height/thickness can be removed using a second iteration of the stealth dicing processes.

In yet another example, the stealth dicing process can be used to remove only known bad dies (e.g., dies that do not pass a quality check, such as a functionality test, a visual inspection, and/or any other suitable testing process) from the wafer. For example, in the partially schematic cross-sectional side view of FIG. 6, first and second voids 624, 626 have been formed in a wafer substrate 620 around only a second semiconductor die 630b. Said another way, the wafer substrate 620 only includes side and bottom cleavage lines 634, 636 around the second semiconductor die 630b. As a result, the second semiconductor die 630b can be removed from the wafer substrate 620 in response to an outward force while the first and third semiconductor dies 630a, 630c will remain in place. The selective removal of known bad dies can allow, for example, the wafer manufacturing process to complete with only functional and/or known good dies remaining on the wafer substrate 620. Additionally, or alternatively, the selective removal can allow a transportation and/or storage process for the wafer substrate 620 to be assessed (e.g., by assessing how many of the remaining, functional and/or known good dies become non-functional and/or known bad dies during transportation and/or storage).

Additionally, or alternatively, the selective removal can allow known bad dies on the wafer substrate 620 to be replaced (or backfilled) by known good dies. FIGS. 7A and 7B are partially schematic cross-sectional side views of an environment for replacing semiconductor dies in the wafer substrate 620 in accordance with various such embodiments of the present technology. As illustrated in FIG. 7A, an upper surface 631 of the second semiconductor die 630b can be engaged by a die-removal component 640 (e.g., the die-removal component 340 of FIGS. 3A-3C or another die-removal component of the present technology). The die-removal component 640 can then lift the second semiconductor die 630b upwards (e.g., generally along or parallel to arrow C) and/or otherwise away from the wafer substrate 620. In the illustrated embodiment, the die-removal component 640 is a picking device configured to individually engage the upper surface 631 of the second semiconductor die 630b. In various other embodiments, the die-removal component 640 can include an adhesive (e.g., a selectively etched die-attach film; an oxide bonding layer, such as an oxide bonding layer that can be selectively debonded using of a laser or other medium; or another suitable adhesive or material) and a carrying wafer, a picking device configured to engage multiple semiconductors, and/or any other suitable component. Additionally, or alternatively, the wafer substrate 620 can be pulled away from the die-removal component 640 (e.g., along a motion path parallel but inverse to arrow C) after the die-removal component 640 engages the second semiconductor die 630b. As a result, the wafer substrate 620 can apply an outward force to a surface of the second semiconductor die 630b facing the wafer substrate 620, thereby pulling the wafer substrate 620 away from the second semiconductor die 630b.

The removal of the second semiconductor die 630b clears a space in the wafer substrate 620 that the die-removal component 640 (or another suitable component) can then fill with a fourth semiconductor die 630d. The fourth semiconductor die 630d can be a known good die that was removed from another wafer (e.g., via a process generally similar to any of the processes discussed above with reference to FIGS. 4-7A). Said another way, the die-removal component 640 can replace the second semiconductor die 630b (FIG. 7A, e.g., when the second die 630b is a non-functional die) with the fourth semiconductor die 630d (e.g., a functional die lifted out of another wafer substrate). The process can then continue to replace any other known bad dies on the wafer substrate 620 to improve a yield from the wafer substrate 620 during a packaging process down the line. Said another way, by backfilling the wafer substrate 620 with known good dies, the selective aspects of the stealth dicing process can improve the yield from the wafer to 100% (or about 100%). The increase in yield increases an efficiency of space usage on the wafer substrate 620, thereby lowering the cost per semiconductor die associated with transporting and/or storing the wafer substrate 620.

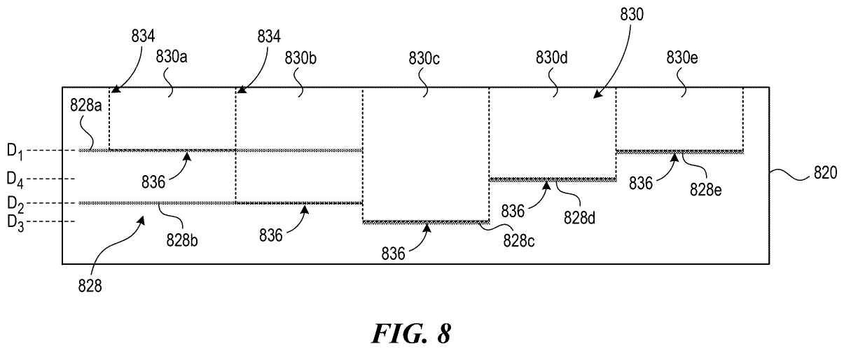

FIG. 8 is a partially schematic cross-sectional side view of a wafer substrate 820 illustrating results from various stealth dicing processes in accordance with further embodiments of the present technology. As illustrated in FIG. 8, the results in the wafer substrate 820 are generally similar to the results in the wafers discussed above with reference to FIGS. 2A-7B. For example, the wafer substrate 820 includes a plurality of semiconductor dies 830 (five illustrated in FIG. 8, identified individually as first through fifth semiconductor dies 830a-830c) that are framed by side and bottom cleavage lines 834, 836. The side and bottom cleavage lines 834, 836 are defined by voids (e.g., the first and second voids 224, 226 of FIG. 2A) that are omitted from FIG. 8 to avoid obscuring details of the technology illustrated with respect to FIG. 8.

For example, the wafer substrate 820 also includes a plurality of cleavage layers 828 at varying depths within the wafer substrate 820. More specifically, the cleavage layers 828 (sometimes also referred to herein as “pre-positioned layers”) can be formed at predetermined depths to help define a lower surface of the semiconductor dies 830 as they are removed from the wafer substrate 820. Said another way, the cleavage layers 828 can be formed to be coplanar with the bottom cleavage lines 836 of the semiconductor dies 830 and configured to help form the voids and/or help a crack propagate horizontally through the wafer substrate 820. In various embodiments, for example, the cleavage layers 828 have a silicon-on-insulator (SOI) composition, a laser-reactive material (e.g., an adhesive that can be reheated and/or reliquefied by the laser), and/or the like. As a result, the cleavage layers 828 can allow better depth control for the stealth dicing process, reduce damage done by the laser during the stealth dicing process, improve surface smoothness at cleavage interfaces (e.g., when the cleavage layers 828 are an adhesive that is undermined by the laser, the material between voids melts and separates smoothly rather than cracking), and/or reduce the chance that a crack propagates outside of an intended cleavage lane. In some embodiments, at least a portion of a cleavage layer 828 can remain on (e.g., a surface) or within a die after the die is singulated from the wafer substrate 820.

As further illustrated in FIG. 8, the cleavage layers 828 can be formed broadly (in a horizontal direction) at predetermined depths or in specific horizontal locations for one or more corresponding semiconductor dies. For example, a first cleavage layer 828a is formed at a first depth D₁ in the wafer substrate 820 within a horizontal footprint of both the first semiconductor die 830a and the second semiconductor die 830b. Similarly, a second cleavage layer 828b is formed at a second depth D₂ in the wafer substrate 820 within a horizontal footprint of both the first and second semiconductor dies 830a, 830b. The first cleavage layer 828a does not interfere with the second semiconductor die 830b during the stealth dicing process because the laser will not be focused at the first depth D₁ and therefore will not transfer enough energy to the first cleavage layer 828a to delaminate the layer. Instead, only the second cleavage layer 828b will have voids formed therein (and/or be at least partially melted). As a result, when an upward force is applied to the second semiconductor die 830b, a crack will only propagate through the wafer substrate 820 generally along the bottom cleavage line 836 at the second depth D₂. Similarly, the second cleavage layer 828b does not interfere with the first semiconductor die 830a during the stealth dicing process because the laser will not be focused at the second depth D₂ and therefore will not transfer enough energy to the second cleavage layer 828b to delaminate the layer.

In another example illustrated in FIG. 8, a third cleavage layer 828c is formed at a third depth D₃ in the wafer substrate 820; a fourth cleavage layer 828d is formed at a fourth depth D₄ in the wafer substrate 820; and a fifth cleavage layer 828e is formed at the first depth D₁ in the wafer substrate 820. Each of the third, fourth, and fifth cleavage layers 828c, 828d, 828e is formed only within the footprint of the corresponding semiconductor die (i.e., the third, fourth, and fifth semiconductor dies 830c, 830d, 830e, respectively). As a result, the third through fifth cleavage layers 828c-828e do not interfere with the stealth dicing process for other semiconductor dies because they are not within the footprint of the other semiconductor dies.

FIG. 9A is a partially schematic cross-sectional side view of a wafer substrate 920 illustrating results from various stealth dicing processes in accordance with further embodiments of the present technology. As illustrated in FIG. 9A, the results in the wafer substrate 920 are generally similar to the results in the wafers discussed above with reference to FIGS. 2A-8. For example, the wafer substrate 920 includes a plurality of semiconductor dies 930 (three illustrated in FIG. 9A, identified individually as first, second, and third semiconductor dies 940, 950, 960) that are framed by cleavage lines 935. Similar to the discussion above, the cleavage lines 935 are defined by voids (e.g., the first and second voids 224, 226 of FIG. 2A) that are omitted from FIG. 9A to avoid obscuring details of the technology illustrated with respect to FIG. 9A.

In the illustrated embodiment, however, the cleavage lines 935 provide a non-traditional frame for each of the semiconductor dies 930. For example, the cleavage lines 935 around the first semiconductor die 940 define multiple regions with different thicknesses. More specifically, the cleavage lines 935 define a perimeter region 942 that is thicker than a central region 944. Said another way, the cleavage lines 935 frame a portion 948 (sometimes also referred to herein as a “thin section”) of the first semiconductor die 940 in the central region 944 of the first semiconductor die 940 that can be removed to form a cavity in the first semiconductor die 940. The cleavage lines 935 also frame a perimeter of the first semiconductor die 940 to at least partially define an outer frame of the first semiconductor die 940. The cleavage lines 935 around the portion 948 can be formed by focusing the laser at a shallower depth than surface 946 of the first semiconductor die 940 and scanning the laser (e.g., the laser 212 of FIG. 2A) along motion paths corresponding to the portion 948 (e.g., similar to the second and/or third motion paths 204, 206 of FIG. 2C). The relatively high thickness of the perimeter region 942 (sometimes also referred to herein as a “thick section”) can help provide mechanical strength and/or structural integrity for the first semiconductor die 940. The relatively low thickness of the central region 944 after removal of the portion 948 can be used, for example, to dope the front of the first semiconductor die 940 (e.g., in or through the central region 944) to form, for example, active regions at a front surface of the first semiconductor die 940. Additionally, or alternatively, the cavity created by removing the portion 948 can be filled with a dielectric, insulating material, and/or any other suitable material to help improve a lifespan of the first semiconductor die 940. In these and other embodiments, the cavity formed by removing the portion 948 can be filled with one or more additional semiconductor components and/or structures.

In another example, the cleavage lines 935 around the second semiconductor die 950 has a multi-stepped profile that traces a plurality of corresponding cavities 956 that are formed at a side 955 of the second semiconductor die 950 (e.g., creating channels/fins, flutes, and/or other grooves; creating a grid, dimples, and/or other patterns; and/or the like) when the second semiconductor die 950 is singulated from the wafer substrate 920. The cavities 956 can be formed, for example, by dynamically focusing a laser (e.g., the laser 212 of FIG. 2A) between two (or more) depths while scanning along the second and/or third motion paths 204, 206 of FIG. 2C. The cavities 956 can increase a surface area on the side 955 of the second semiconductor die 950 that is expected to help increase thermal dissipation off of the side 955 of the second semiconductor die 950. As a result, for example, the second semiconductor die 950 can be a suitable top die for a stacked semiconductor device to help increase thermal dissipation off of the stacked semiconductor device. FIG. 9B is a partially schematic cross-sectional side view of a stacked semiconductor device 900 configured in accordance with some such embodiments of the present technology.

As illustrated in FIG. 9B, the stacked semiconductor device 900 includes a base substrate 910 (e.g., an interposer, a PCB, and/or any other suitable base substrate) and a die stack 912 carried by the base substrate 910. The die stack 912 includes a plurality of lower semiconductor dies 914 that each has a traditional (e.g., rectangular) shape and the second semiconductor die 950 carried by the lower semiconductor dies 914 (e.g., arranged in a stack with the lower semiconductor dies 914). Heat generated in the die stack 912 can be thermally communicated toward outer surfaces of the die stack 912, including the side 955 of the second semiconductor die 950 (e.g., positioned as the uppermost surface of the die stack 912). The cavities 956 at the side 955 of the second semiconductor die 950 can then help dissipate heat from the side 955, thereby improving thermal dissipation out of the die stack 912.

Although shown as formed within the wafer substrate 920 of FIG. 9A, the cavities 956 and/or other cutouts, recesses, slots, or other features can be formed at the die level (after the second semiconductor die 950 is singulated from the wafer substrate 920 and/or after the second semiconductor die 950 is positioned in the die stack 912). In some embodiments, the cavities 956 and/or other cutouts, recesses, slots, or other features can be formed in the second semiconductor die 950 at the die level using lasers and/or other techniques generally similar to the wafer-level stealth dicing techniques disclosed herein.

Returning to the non-traditional die profiles illustrated in FIG. 9A, the cleavage lines 935 can define a stepped profile for the third semiconductor die 960. For example, in the illustrated embodiment, a side 965 of the third semiconductor die 960 includes a step 966 (e.g., a cutout, a slot, a recess). In some embodiments, the step 966 can be formed at a front side of the third semiconductor die 960. In these and other embodiments, a portion of the wafer substrate 920 can be positioned above the step 966 when the step 966 is formed, and can be removed (e.g., before or after the third semiconductor die 960 is removed from the wafer substrate 920). The step 966 can be formed, for example, by focusing a laser (e.g., the laser 212 of FIG. 2A) at a first depth to trace a perimeter of the third semiconductor die 960, then focusing the laser at a second depth to trace a central portion of the third semiconductor die 960. In another example, the step 966 can be formed by dynamically focusing the laser between two (or more) depths while scanning along the second and/or third motion paths 204, 206 of FIG. 2C. In some embodiments, the step 966 is formed around a complete perimeter of the third semiconductor die 960. In some embodiments, the third semiconductor die 960 includes one or more discrete steps that are formed around a portion of the perimeter (e.g., forming one or more crenellations around the perimeter of the third semiconductor die 960).

The step 966 can be utilized to, for example, form wirebond locations to reduce an overall height of the die stack (e.g., by lowering a height of an uppermost wirebond location), expose a metallization layer within the third semiconductor die 960 for direct bonding, and/or the like. Additionally, or alternatively, the step 966 can be utilized to form intermediate connections with dies in a die stack. FIG. 9C is a partially schematic cross-sectional side view of a portion of a die stack 916 configured in accordance with some such embodiments of the present technology. As illustrated in FIG. 9C, the third semiconductor die 960 can be positioned below one or more upper dies 918 (one illustrated in FIG. 9C) in the die stack 916. The step 966 formed in the third semiconductor die 960 can provide access to a surface of the third semiconductor die 960, which can have a bond site 968 formed thereon. The bond site 968, in turn, can be coupled to a wirebond 970 to provide direct access to the third semiconductor die 960 via the wirebond 970 (e.g., in contrast to accessing the third semiconductor die 960 through one or more TSV chains in the die stack 916, a series of wirebonds, and/or the like).

FIG. 10 is a partially schematic cross-sectional side view of a wafer substrate 1020 illustrating results from various stealth dicing processes in accordance with further embodiments of the present technology. As illustrated in FIG. 10, the results in the wafer substrate 1020 are generally similar to the results in the wafers discussed above with reference to FIGS. 2A-9A. For example, the wafer substrate 1020 includes a plurality of semiconductor dies 1030 (two illustrated in FIG. 10, identified individually as first and second semiconductor dies 1030a, 1030b) that are framed by cleavage lines 1035. Similar to the discussion above, the cleavage lines 1035 are defined by voids (e.g., the first and second voids 224, 226 of FIG. 2A) that are omitted from FIG. 10 to avoid obscuring details of the technology illustrated with respect to FIG. 10.

As further illustrated in FIG. 10, the cleavage lines 1035 can include one or more angled portions 1037 that can define a non-traditional shape for the semiconductor dies 1030. For example, at least a portion of the cleavage lines 1035 corresponding to the sidewalls of the semiconductor dies 1030 can be at a non-zero, non-perpendicular angle with respect to a vertical axis through the wafer substrate 1020 (e.g., sloped with respect to the vertical axis) and/or a non-zero, non-perpendicular angle with respect to a horizontal axis through the wafer substrate 1020. As specific examples, the angled portions 1037 can define a beveled edge for the first semiconductor die 1030a and a tapered edge for the second semiconductor die 1030b. The angled portions 1037 can be formed by (a) focusing a laser (e.g., the laser 212 of FIG. 2A) at a plurality of depths along the angled portions 1037 and (b) tracing a perimeter of the corresponding semiconductor die at each of the plurality of predetermined depths (e.g., similar to the first motion paths 202 of FIG. 2B, laterally offset at each of the plurality of predetermined depths). Additionally, or alternatively, the angled portions 1037 can be formed by dynamically focusing the laser at a plurality of depths while scanning along the second and/or third motion paths 204, 206 of FIG. 2C. Accordingly, although FIG. 10 illustrates a few specific examples of possible shapes that can be formed with the angled portions 1037, one of skill in the art will understand that the technology is not so limited. Instead, any suitable shape can be formed by focusing the laser along the shape to form the cleavage lines 1035, then applying various stresses to the wafer substrate 1020 to propagate cracks along the cleavage lines 1035.

Further, because cracks are expected to propagate between adjacent voids, the stealth dicing process can form a generally curved surface. For example, the stealth dicing process can form the voids in predetermined locations according to a planned curved profile. Then, the stealth dicing process can apply stress to the wafer, causing cracks to propagate between adjacent voids. While the crack between two adjacent voids may have a generally straight path, the voids can be formed close enough together that the resulting surface has a generally curved profile. Accordingly, the non-traditional shape can allow the semiconductor dies to be formed custom to a space available in a stacked semiconductor device and/or according to any other space constraint.

### CONCLUSION

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A stealth dicing method, comprising:
forming a first cleavage line in a wafer, the first cleavage line extending generally in a first direction and defining a first surface corresponding to a sidewall of a semiconductor die; and
forming a second cleavage line in the wafer, the second cleavage line extending generally in a second direction and defining a second surface oriented generally perpendicular to the first surface, wherein the second surface corresponds to at least a portion of a top surface or at least a portion of a bottom surface of the semiconductor die.

2. The stealth dicing method of claim 1, wherein forming the second cleavage line includes forming the second cleavage line using a laser.

3. The stealth dicing method of claim 2, wherein forming the second cleavage line using the laser includes:
focusing the laser at a first depth into the wafer;
scanning the laser along a first motion path, wherein the first motion path includes a plurality of scribe lines that pass through a central region of the semiconductor die; and
forming a plurality of voids at the first depth within the wafer and at a corresponding plurality of locations along the first motion path such that the second cleavage line defines the second surface.

4. The stealth dicing method of claim 1, wherein:
the semiconductor die is a first semiconductor die;
the second cleavage line is positioned a first depth into the wafer;
the method further comprises—
forming a third cleavage line in the wafer, the third cleavage line extending generally in the first direction and defining a third surface corresponding to a sidewall of a second semiconductor die, and
forming a fourth cleavage line in the wafer, the fourth cleavage line extending generally in the second direction and defining a fourth surface oriented generally perpendicular to the third surface; and
the fourth surface corresponds to at least a portion of a top surface or at least a portion of a bottom surface of the second semiconductor die, and is positioned at a second depth into the wafer that is different from the first depth.

5. The stealth dicing method of claim 1, wherein:
the second cleavage line intersects the first cleavage line;
the method further comprises forming a step profile into the sidewall of the semiconductor die;
forming the step profile includes forming a third cleavage line in the wafer;
the third cleavage line extends generally in the first direction, intersects the second cleavage line, and defines a third surface corresponding to the sidewall of the semiconductor die; and
the third surface is oriented generally parallel to the first surface and generally perpendicular to the second surface.

6. The stealth dicing method of claim 1, wherein:
the method further comprises forming a cutout in a central region of the semiconductor die such that a thickness of the central region of the semiconductor die is less than a thickness of a perimeter region of the semiconductor die that is positioned about the central region;
the second surface corresponds to a surface of the cutout;
forming the cutout includes forming a third cleavage line and a fourth cleavage line in the wafer;
the third and fourth cleavage lines extend generally in the first direction, intersect the second cleavage line, and define third and fourth surfaces, respectively, corresponding to (i) the top surface or the bottom surface of the semiconductor die and (ii) the cutout.

7. The stealth dicing method of claim 1, further comprising forming a third cleavage line in the wafer, wherein the third cleavage line (i) extends generally in a third direction different from first and second direction, and (ii) defines a third surface of the semiconductor die that is oriented at one or more non-perpendicular angles with respect to the first and second surfaces.

8. The stealth dicing method of claim 1, further comprising singulating the semiconductor die from the wafer.

9. The stealth dicing method of claim 8, wherein singulating the semiconductor die from the wafer includes (i) attaching the semiconductor die to a carrier wafer and (ii) pulling the carrier wafer away from the wafer to apply an outward force to a surface of the semiconductor die facing the carrier wafer.

10. The stealth dicing method of claim 8, wherein singulating the semiconductor die from the wafer includes engaging and lifting an exposed surface of the semiconductor die with a picking device.

11. The stealth dicing method of claim 8, wherein:
the semiconductor die is a first semiconductor die;
the wafer further includes a second semiconductor die;
the method further comprises—
testing the first semiconductor die and the second semiconductor die, and
based at least in part on the testing, identifying the first semiconductor die as a functional die and the second semiconductor die as a non-functional die; and
singulating the first semiconductor die includes singulating the first semiconductor die from the wafer without singulating the second semiconductor die from the wafer.

12. The stealth dicing method of claim 8, wherein:
the semiconductor die is a first semiconductor die;
the wafer further includes a second semiconductor die;
the method further comprises—
testing the first semiconductor die and the second semiconductor die, and
based at least in part on the testing, identifying the first semiconductor die as a non-functional die and the second semiconductor die as a functional die; and
singulating the first semiconductor die includes singulating the first semiconductor die from the wafer without singulating the second semiconductor die from the wafer.

13. The stealth dicing method of claim 12, further comprising:
identifying a third semiconductor die as a functional die; and
after singulating the first semiconductor die from the wafer, backfilling the first semiconductor die in the wafer with the third semiconductor die.

14. A method of singulating semiconductor dies from a wafer, the method comprising:
singulating a first semiconductor die having a first thickness from a wafer, wherein singulating the first semiconductor die from the wafer includes forming a first cleavage line at a first depth into the wafer, and wherein forming the first cleavage line comprises:
focusing a laser at the first depth into the wafer,
scanning the laser along a first motion path, wherein the first motion path includes a plurality of first scribe lines that pass through a central region of the first semiconductor die, and
forming a plurality of first voids at the first depth within the wafer and at a corresponding plurality of locations along the first motion path such that the first cleavage line defines at least a portion of a top surface or at least a portion of a bottom surface of the first semiconductor die; and
singulating a second semiconductor die having a second thickness from the wafer, wherein the second thickness is different from the first thickness, wherein singulating the second semiconductor die from the wafer includes forming a second cleavage line at a second depth into the wafer that is different from the first depth, and wherein forming the second cleavage line comprises:
focusing the laser at the second depth into the wafer,
scanning the laser along a second motion path, wherein the second motion path includes a plurality of second scribe lines that pass through a central region of the second semiconductor die, and
forming a plurality of second voids at the second depth within the wafer and at a corresponding plurality of locations along the second motion path such that the second cleavage line defines at least a portion of a top surface or at least a portion of a bottom surface of the second semiconductor die.

15. The method of claim 14, wherein:
the wafer includes a first pre-positioned cleavage layer at the first depth and a second pre-positioned cleavage layer at the second depth;
singulating the first semiconductor die includes scanning, with the laser focused at the first depth, the laser along at least a portion of the first pre-positioned cleavage layer; and
singulating the second semiconductor die includes scanning, with the laser focused at the second depth, the laser along at least a portion of the second pre-positioned cleavage layer.

16. The method of claim 14, wherein:
the wafer further includes a third semiconductor die different from the first and second semiconductor dies;
the method further comprises:
identifying the first and second semiconductor dies as functional semiconductor dies, and
identifying the third semiconductor die as a defective semiconductor die; and
singulating the first and second semiconductor dies includes singulating the first and second semiconductor dies without singulating the third semiconductor die.

17. The method of claim 14, wherein:
the wafer further includes a third semiconductor die different from the first and second semiconductor dies;
the method further comprises:
identifying the first and second semiconductor dies as defective semiconductor dies, and
identifying the third semiconductor die as a functioning semiconductor die; and
singulating the first and second semiconductor dies includes singulating the first and second semiconductor dies without singulating the third semiconductor die.

18. A semiconductor device, comprising:
a semiconductor die having a plurality of sidewalls, a top surface, and a bottom surface opposite the top surface, wherein the semiconductor die includes a thickness corresponding to a distance between the bottom surface and the top surface, and wherein the top surface or the bottom surface corresponds to a stealth dicing cleavage line.

19. The semiconductor device of claim 18, wherein:
the semiconductor die is a first semiconductor die, the thickness is a first thickness, and the distance is a first distance; and
the semiconductor die further includes a second semiconductor die arranged in a stack with the first semiconductor die, the second semiconductor die having a plurality of sidewalls, a top surface, and a bottom surface opposite the top surface, wherein the second semiconductor die includes a second thickness corresponding to a second distance between the bottom surface and the top surface of the second semiconductor die, and wherein the second thickness is different from the first thickness.

20. The semiconductor device of claim 19, wherein the stealth dicing cleavage line is a first stealth dicing cleavage line, and wherein the top surface or the bottom surface of the second semiconductor die corresponds a second stealth dicing cleavage line.
